(19) United States
(12) Patent Application Publication
(10) Pub. No.: US 2009/0153160 A1
(43) Pub. Date: Jun. 18, 2009

(54) CIRCUIT BOARD TEST CLAMP

(75) Inventor: FA-SHENG HUANG, Shenzhen (CN)

Correspondence Address: PCE INDUSTRY, INC.;ATT. Steven Reiss, 458 E. LAMBERT ROAD, FULLERTON, CA, 92835, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 11/967,059

(22) Filed: Dec. 29, 2007

(30) Foreign Application Priority Data
Dec. 14, 2007 (CN) 200710203085.3

(51) Int. Cl. G01R 1/04

(52) U.S. Cl. 324/754

(57) ABSTRACT

A circuit board test clamp is configured to test a circuit board via a tester having a probe. The circuit board test clamp includes a clamping element configured to clamp on the circuit board and a testing element mounted on the clamping element. The testing element includes a first test probe and a second test probe. When the circuit board is clamped by the clamping element, the first test probe electrically contacts a test point of the circuit board, and the second test probe is electrically connected to the probe of the tester.

### BACKGROUND

1. Field of the Invention

The present invention relates to test apparatuses, and particularly to a test clamp which is used to test a circuit board via a tester.

2. Description of Related Art

Before a circuit board such as a double data rage (DDR) memory is sold, it will be tested. When a circuit board is tested, each test point of the circuit board should be welded to a terminal of an extension metal line thereon. When a probe of a tester contacts the other terminal of the extension metal line, the tester will test the test point of the circuit board.

However, this test method has same disadvantages. Firstly, this test method requires metal extension lines be welded to the test points of the circuit board, which is unduly laborious and time-consuming and may damage the circuit board. Secondly, the joints of the extension lines and the test points of the circuit board may be rosin joints, which may influence the test quality.

What is desired, therefore, is to provide a circuit board test clamp which overcomes the above problems.

### SUMMARY

An embodiment of a circuit board test clamp is configured to test a circuit board via a tester having a probe. The circuit board test clamp includes a clamping element configured to clamp on the circuit board and a testing element mounted on the clamping element. The testing element includes a first test probe and a second test probe. When the circuit board is clamped by the clamping element, the first test probe electrically contacts a test point of the circuit board, and the second test probe is electrically connected to the probe of the tester.

Other advantages and novel features of the present invention will become more apparent from the following detailed description of an embodiment when taken in conjunction with the accompanying drawings, in which:

### BRIEF DESCRIPTION OF THE DRAWINGS

FIG. 1 is a perspective view of a circuit board test clamp in accordance with an embodiment of the present invention;

FIG. 2 is a left side elevational view of FIG. 1;

FIG. 3 is a perspective view of the circuit board test clamp of FIG. 1 clamping a circuit board;

FIG. 4 is a left side elevational view of FIG. 3;

FIG. 5 is a perspective view of the circuit board test clamp of FIG. 1 clamping a circuit board and a probe of a tester; and

FIG. 6 is a left side elevational view of FIG. 5.

### DETAILED DESCRIPTION

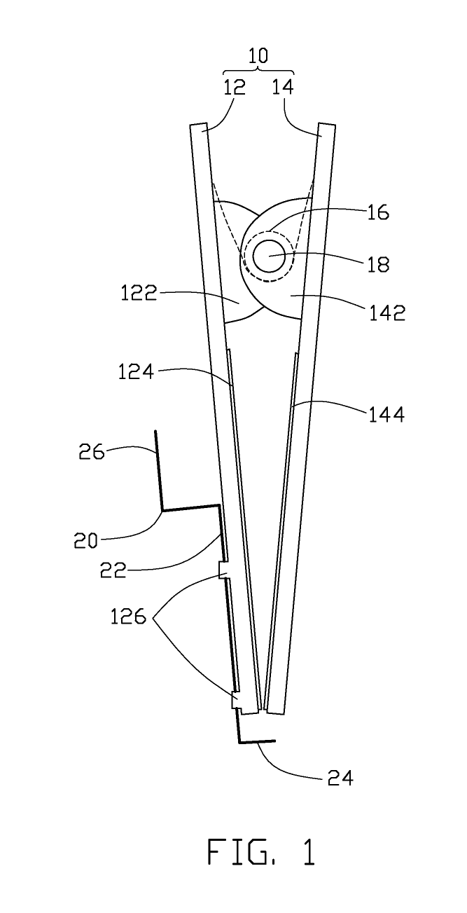

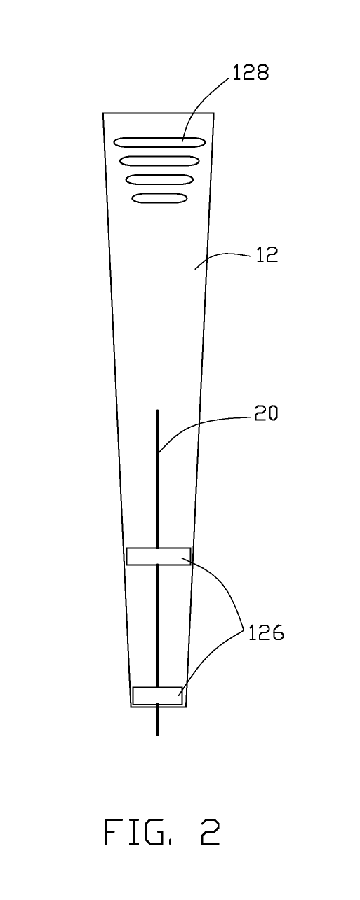

Referring to FIGS. 1 and 2, a circuit board test clamp in accordance with an embodiment of the present invention includes a clamping element 10 and a testing element 20. The clamping element 10 includes two clamping boards 12 and 14, and a torsion spring 16. The clamping boards 12 and 14 respectively include two semicircular connecting portions 122 and 142 mounted facing each other and are adjacent to corresponding ends thereof. The semicircular connecting portions 122 and 142 each define a round through hole (not marked) therein, the holes are coaxially aligned.

In assembly, the torsion spring 16 is coiled around a cylindrical coiling portion 18. Two ends of the coiling portion 18 are respectively inserted into the two through holes of the connecting portions 122 and 142. Thereby, the clamping element 10 has a clamping function. Inner sides of the connecting portions 122 and 142 respectively include two insulating skidproof layers 124 and 144 attached thereon.

In this embodiment, the testing element 20 includes a connecting portion 22, and two test probes 24 and 26 respectively extending from opposite ends of the connecting portion 22. The connecting portion 22 is mounted on the clamping board 12 via two mounting elements 126. The test probe 24 is perpendicular to an end of the connecting portion 22 and adjacent to a distal end of the clamping board 12 for contacting a test point of a circuit board, which needs to be tested. The test probe 26 perpendicularly extends from the other end of the connecting portion 22 for electrically connecting to a probe of a tester. The outward facing sides of the clamping boards 12 and 14 define a plurality of parallel skidproof grooves 128 therein.

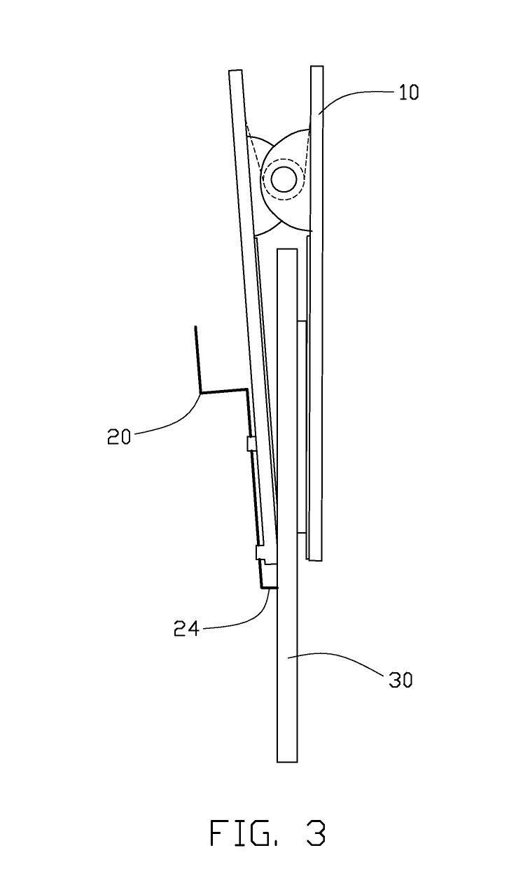

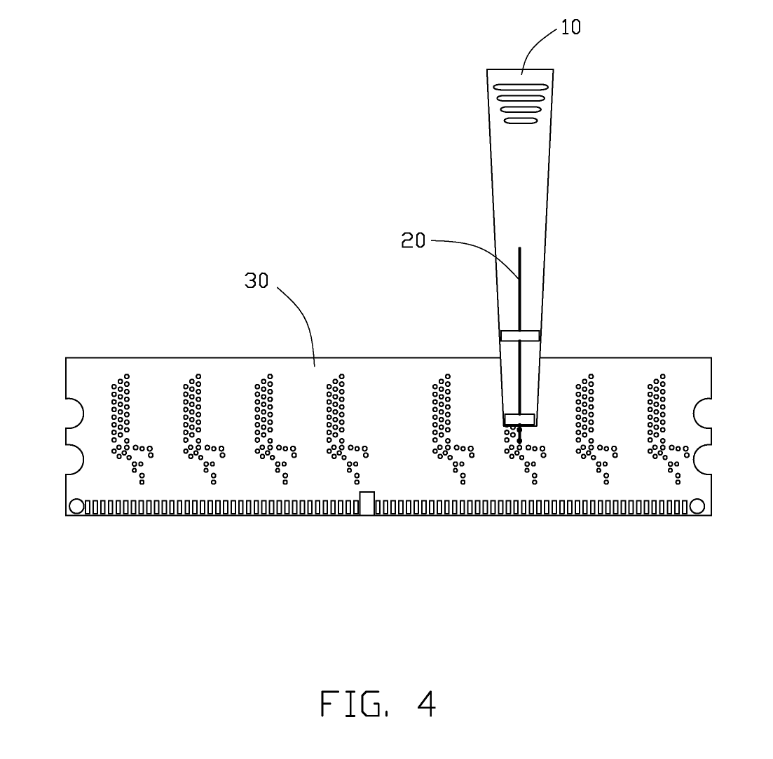

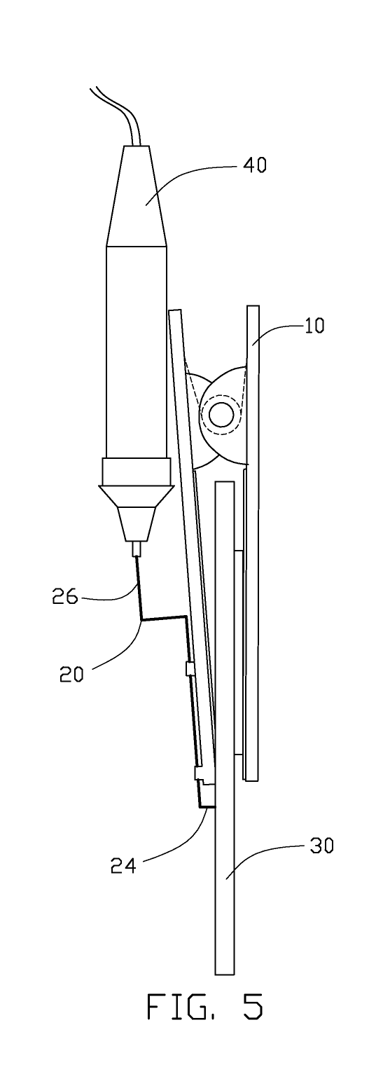

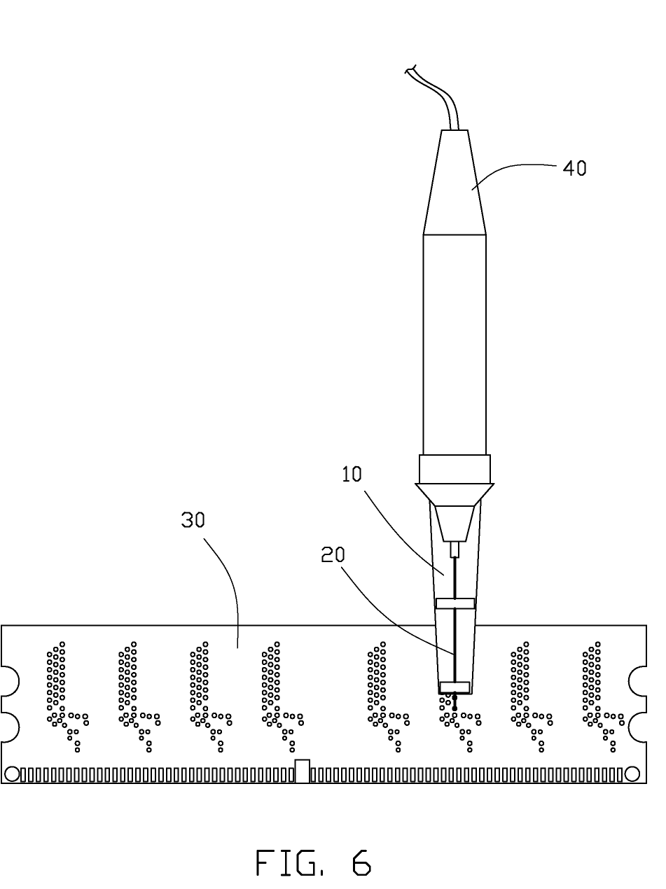

Referring also to FIGS. 3 to 6, when a circuit board 30 such as a memory is tested, the circuit board 30 is clamped by the clamping element 10 of the circuit board test clamp, and the test probe 24 electrically contacts a test point of the circuit board 30. And then, a probe 40 of a tester is electrically connected to the test probe 26, thereby the tester will test the test point of the circuit board 30 via the circuit board test clamp, which is very convenient. If the circuit board 30 has a plurality of test points, users can use plurality of circuit board test clamps to respectively test these test points, which can increase test efficiency.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. A circuit board test clamp comprising:
a clamping element configured to clamp on one side of a circuit board; and
a testing element mounted on the clamping element, the testing element comprising a first test probe and a second test probe electrically connected to the first test probe, when the clamping element clamps on the one side of the circuit board, the first test probe is capable of selectively electrically contacting one or more test points of the circuit board, and the second test probe is capable of being electrically connected to a test probe of a tester, such that the test points of the circuit board are capable of being selectively electrically connected to the test probe of the tester via the testing element.

2. The circuit board test clamp as claimed in claim 1, wherein the clamping element comprises two clamping boards, and a torsion spring, the two clamping boards respectively comprise a connecting portions mounted facing each other and are adjacent to corresponding ends thereof, the two connecting portions each define a through hole therein, the torsion spring is coiled around a coiling portion, two ends of the coiling portion are respectively inserted into the two through hole of the two connecting portions.

3. The circuit board test clamp as claimed in claim 2, wherein the connecting portions are semicircular.

4. The circuit board test clamp as claimed in claim 2, wherein the through holes are round.

5. The circuit board test clamp as claimed in claim 2, wherein the coiling portion is cylindrical.

6. The circuit board test clamp as claimed in claim 2, wherein inner sides of the two connecting portions respectively include two insulating skidproof layers attached thereon.

7. The circuit board test clamp as claimed in claim 2, wherein the outward facing sides of the clamping boards define a plurality of parallel skidproof grooves therein.

8. The circuit board test clamp as claimed in claim 2, wherein the second test probe of the testing element is perpendicular to an end of the connecting portion and adjacent to a distal end of the clamping board for contacting a test point of the circuit board which needs to be test.
